(19) United States
(12) Patent Application Publication
(10) Pub. No.: US 2008/0247309 A1
(43) Pub. Date: Oct. 9, 2008

(54) Method And Device For Realizing Primary-Backup Protective Of Low Order Cross Apparatus

(75) Inventor: Longbing Ran, Shenzhen (CN)

Correspondence Address: HARNESS, DICKEY & PIERCE, P.L.C., P.O. BOX 828, BLOOMFIELD HILLS, MI, 48303, US

(73) Assignee: Huawei Technologies Co., Ltd., Shenzhen (CN)

(21) Appl. No.: 12/140,546

(22) Filed: Jun. 17, 2008

Related U.S. Application Data
(63) Continuation of application No. PCT/CN2006/003160, filed on Nov. 24, 2006.

(30) Foreign Application Priority Data
May 11, 2006 (CN) 200610060645.X

(51) Int. Cl. G01R 31/08

(52) U.S. Cl. 370/228

(57) ABSTRACT

A method and device are used for realizing primary-backup protective of low order cross apparatus of SDH low order virtual container deploy based on switching network. The method includes distributing multicast ID as the destination address of code flow of high order virtual container, wherein the high order virtual container includes SDH low order virtual container to be deployed and the multicast ID is directed respectively to the port connected to the two or more than two low order cross apparatuses in switching network; closing the connected channel between the switching network and said backup low order cross apparatus; and opening the connected channel between the switching network and one of the backup low order cross apparatus when the primary low order cross apparatus fails. The method can efficiently perform primary-backup rearrangement when SDH low order virtual container is deployed based on switching network.

### CROSS-REFERENCE TO RELATED APPLICATIONS

This application is a continuation of International Application No. PCT/CN2006/003160, filed Nov. 24, 2006. This application claims the benefit of Chinese Application No. 200610060645.X, filed May 11, 2006. The disclosures of the above applications are incorporated herein by reference.

### FIELD

The present disclosure relates to the field of Synchronous Digital Hierarchy (SDH) transport and in particular to a method and device for implementing primary-secondary protection of a low-order cross device.

### BACKGROUND

The statements in this section merely provide background information related to the present disclosure and may not constitute prior art.

Scheduling of an SDH virtual container refers to that a high-order or low-order virtual container via an SDH port of an SDH transport device passes as a whole through the device and then is transported from a high- or low-order virtual container via an SDH port of the device. The device may modify an overhead in the virtual container during this procedure.

Currently, technologies for scheduling an SDH virtual container in Multi-Service Provisioning Platform (MSPP)/Multi-Service Transporting Platforms (MSTP) have been mature, and technologies based upon space division and time division crossing are mature technologies used in MSTP products. FIG. 1 illustrates a commonly used method for scheduling an SDH virtual container in the MSPP/MSTP, where circled reference numbers 1 to N denote SDH interfaces.

A procedure for implementing SDH virtual container scheduling is described briefly as follows.

1. An SDH frame processing module performs operations of framing, pointer processing, overhead processing, etc., on an SDH frame via an SDH interface, and transports the processed SDH frame to an SDH virtual container cross connection module.

2. The SDH virtual container cross connection module schedules an SDH virtual container, which is to be scheduled, in the received SDH frame. This can be implemented by means well known to those skilled in the art, such as with the use of space division and time division crossing technologies. After accomplishing the virtual container scheduling, the SDH virtual container is transported to an SDH frame processing module at an exit.

3. The SDH frame processing module at the exit processes the received SDH virtual container and then transports the processed virtual container via an SDH interface.

Although the technologies for scheduling and transporting an SDH virtual container in the MSPP/MSTP have been mature, the MSPP/MSTP architecture may be limited in terms of transporting a data service.

General Multi-service Packet Switching (GMPS) is new technology for switching between respective modules of a device, which emerges as networks evolve. GMPS uses a uniform switching plane to accomplish switching of an SDH virtual container and multiple services such as data service. A method for implementing GMPS at present includes using a Fabric Switch to accomplish switching of an SDH virtual container and data. An external interface used when GMPS is used to implement SDH virtual container scheduling is the same as a traditional SDH interface. FIG. 2 is a schematic diagram illustrating a method for implementing SDH virtual container scheduling by the use of GMPS in the prior art, where circled reference numbers 1 to N denote SDH interfaces.

A procedure for implementing SDH virtual container scheduling is as follows.

1. An SDH frame processing module performs operations of framing, pointer processing, overhead processing, etc., on an SDH frame via an SDH interface, and transports the processed SDH frame to a subsequent slicing module.

2. Dependent upon a high-order virtual container to be scheduled or a low-order virtual container to be scheduled, the slicing module slices a bit stream including the virtual container, encapsulates the sliced bit stream into the payload of a cell, fills in the cell head of the cell a switching network address corresponding to a destination assembly module as the destination address of the cell, and then transports the cell to the switching network.

3. The switching network transports the cell to the destination assembly module dependent upon the destination address in the cell head upon reception of the cell.

4. The destination assembly module assembles the cell into an SDH frame, and then transports the SDH frame to an SDH frame processing module at an exit.

5. The SDH frame processing module at the exit processes the received SDH frame, and transport the processed SDH frame via an SDH interface, thereby implementing the SDH virtual container scheduling.

This solution in the prior art is applicable to implementing SDH high-order virtual container scheduling, but not to implementing SDH low-order virtual container scheduling. The reasons are as follows.

Firstly, when a bit stream including an SDH virtual container to be scheduled is sliced, the sliced bit stream typically has to be collected into the payload of a cell. Therefore, in the above solution, slicing of a bit stream including an SDH high-order virtual container results in a relatively short waiting time due to a relatively high rate of the bit stream, while slicing of a bit stream including an SDH low-order virtual container results in a relatively long waiting time due to a relatively low rate of the bit stream. Consequently, a large delay occurs when the above solution is used to implement SDH low-order virtual container scheduling, while there may be a strict requirement on the delay for transport of an SDH virtual container.

Secondly, since slicing of a bit stream including a low-order virtual container shall be taken into account for each line card, costs of the slicing and assembly modules may be much higher compared to those of MSPP/MSTP products.

In order to solve the above problem of the large delay and the high cost when GMPS is used to implement the SDH low-order virtual container scheduling, there has been proposed a method for implementing SDH virtual container scheduling based upon a switching network in which a switching network is used to implement SDH high-order virtual container scheduling, and the switching network and a low-order cross device connected to the switching network are used to implement SDH low-order virtual container scheduling.

FIG. 3 is a schematic diagram illustrating an embodiment for implementing this method, where circled reference numbers 1 to N denote SDH interfaces, and circled denotations P and S denote respectively a primary low-order cross device and a secondary low-order cross device each including a low-order cross module, a high-order assembly module connected to the low-order cross module, and a high-order slicing module connected to the low-order cross module. In various embodiments, the SDH frame processing module performs operations of framing, pointer processing, overhead processing, etc., on an SDH frame received via an SDH interface, the function of which can be implemented by use of a chip called Framer. The high-order slicing module receives the SDH frame from the SDH frame processing module, slices a bit stream including a high-order virtual container dependent upon an SDH high-order virtual container to be scheduled or a high-order virtual container in which an SDH low-order virtual container to be scheduled lies, and converts the sliced bit stream into a cell identifiable by a switching network. The high-order assembly module implements a reverse procedure relative to that of the high-order slicing module by assembling the cell from the switching network into an SDH frame. The primary low-order cross device and the secondary low-order cross device are used for performing cross connection of a low-order virtual container in a way that the former acts as a low-order cross device for currently performing cross connection of the low-order virtual container, and the latter is used for performing cross connection of the low-order virtual container when the primary low-order cross device fails.

In FIG. 3, the low-order cross modules in the primary low-order cross device and the secondary low-order cross device are core modules for implementing cross connection of an SDH low-order virtual container, the implementing procedure of which is the same as that in FIG. 1 in which the SDH virtual container cross connection module performs cross connection of a low-order virtual container. This procedure will be described briefly with reference to FIG. 4. The high-order assembly module receives a cell from the switching network, assembles the received cells into an SDH frame, and then transports the SDH frame to the low-order cross module, where the cell is obtained through slicing a bit stream including a high-order virtual container dependent upon the high-order virtual container in which a low-order virtual container to be scheduled lies. The processing procedure in the low-order cross module is as follows: a frame searching module searches the received SDH frame for A1 and A2, and performs pointer processing on the received SDH frame; a low-order overhead processing module performs overhead processing on the pointer processed SDH frame; subsequently a time slot cross module performs time slot crossing on the overhead processed SDH frame; and then optionally a subsequent low-order overhead processing module performs overhead modification, and finally a frame regeneration module regenerates and supplies a complete SDH frame to the high-order slicing module. A cross connection of the low-order virtual container can thus be accomplished in such a procedure. A low-order virtual container, the exit of which is only the same destination service port, is mapped into one or more high-order virtual containers. Thereafter, dependent upon a high-order virtual container in which the cross-connected low-order virtual container lies, the high-order slicing module slices a bit stream including the high-order virtual container, converts the sliced bit stream into a cell, and transports the cell to the switching network.

The above SDH frame processing module, high-order slicing module, high-order assembly module and low-order cross module can all be implemented by means well known to those skilled in the art. It can be readily appreciated that scheduling of an SDH virtual container is configured in advance and the above operations are performed according to the configuration.

A procedure for performing SDH high-order virtual container scheduling by a method for implementing SDH virtual container scheduling on the basis of a switching network is described below with reference to FIG. 3.

1. An SDH frame processing module receives an SDH frame via an SDH interface, processes the SDH frame, and transports the processed SDH frame to a subsequent slicing module.

2. On the basis of an SDH high-order virtual container to be scheduled, the slicing module slices a bit stream including the high-order virtual container, fills the sliced bit stream into the payload of a cell, fills in the cell head of the cell an address of a switching network corresponding to a destination assembly module as a destination address of the cell, and transports the cell to the switching network.

3. The switching network transports the cell to the destination assembly module dependent upon the destination address in the cell head upon reception of the cell.

4. The destination assembly module collects the cell, recovers the collected cells into an SDH frame, and then transports the SDH frame to an SDH frame processing module at an exit.

5. The SDH frame processing module at the exit processes the received SDH frame, and transports the processed SDH frame via an SDH interface, thereby implementing the high-order virtual container scheduling.

A procedure for performing SDH low-order virtual container scheduling by a method for implementing SDH virtual container scheduling based upon a switching network will be described below with reference to FIG. 3.

1. An SDH frame processing module receives an SDH frame via an SDH interface, processes the SDH frame, and transports the processed SDH frame to a subsequent high-order slicing module.

2. On the basis of a high-order virtual container in which an SDH low-order virtual container to be scheduled lies, the high-order slicing module slices a bit stream including the high-order virtual container, fills the sliced bit stream into the payload of a cell, fills in the cell head of the cell an address of a switching network corresponding to a primary low-order cross module (a low-order cross module in a primary low-order cross device) as a destination address of the cell, and transports the cell to the switching network.

3. The switching network transports the cell to a high-order assembly module to which the primary low-order cross module is connected according to the destination address in the cell head upon reception of the cell, and the high-order assembly module collects the cell, recovers the collected cells into an SDH frame, and then transports the SDH frame to the primary low-order cross module.

4. The primary low-order cross module cross-connects the low-order virtual container, maps the cross-connected low-order virtual container into an SDH frame, and supplies the SDH frame to a high-order slicing module connected to the primary low-order cross module.

5. The high-order slicing module receives the SDH frame from the primary low-order cross module, and dependent upon a high-order virtual container in which the cross-connected SDH low-order virtual container lies, slices a bit stream including the high-order virtual container, converts the sliced bit stream into a cell, fills in the cell head of the cell an address of a switching network corresponding to a destination high-order assembly module as a destination address of the cell, and transports the cell to the switching network.

6. The switching network transports the cell to the destination high-order assembly module dependent upon the destination address in the cell head upon reception of the cell.

7. The destination high-order assembly module recovers the cell into an SDH frame, and then transports the SDH frame to an SDH frame processing module at an exit.

8. The SDH frame processing module at the exit processes the received SDH frame, transports the processed SDH frame via an SDH interface, thereby implementing the low-order virtual container scheduling.

It should be noted that with respect to the step 2, the high-order slicing module can slice the bit stream including only the high-order virtual container in which the SDH low-order virtual container to be scheduled lies; or alternatively can slice a bit stream including the high-order virtual container in which the SDH low-order virtual container to be scheduled lies and relevant overheads, pointers, etc. Further with respect to the step 4, the primary low-order cross module can encapsulate the cross-connected SDH virtual container into an SDH frame, and then supply the SDH frame to a high-order slicing module connected to the primary low-order cross module; or alternatively can supply the cross-connected SDH virtual container directly to the high-order slicing module in the structural form of a Virtual Container (VC), a Tributary Unit (TU), an Administrative Unit (AU), etc.

The above procedure for implementing the SDH low-order virtual container scheduling is analyzed as follows. The high-order slicing module performs slicing dependent upon an SDH high-order virtual container, i.e., performs slicing regarding the high-order virtual container as a whole. With respect to a cell obtained from such slicing, a switching network may only perform scheduling on a whole of the SDH high-order virtual container, and may not perform scheduling individually on a low-order virtual container in the high-order virtual container. The low-order virtual container scheduling is accomplished by use of a low-order cross device. In other words, the low-order cross device schedules the SDH low-order virtual container, which is to be scheduled, onto a corresponding low-order virtual container of the corresponding SDH high-order virtual container.

As mentioned above, a secondary low-order cross device is used to participate in scheduling of a low-order virtual container for protection upon failure of a primary low-order cross device. When performing SDH low-order virtual container scheduling according to the above procedure, if the primary low-order cross device is found failure, then primary-secondary switching is performed as follows.

1. It is determined that the primary low-order cross device fails.

2. In a high-order slicing module connected to an SDH frame processing module, a destination address of a cell obtained from conversion of a bit stream including a high-order virtual container in which an SDH low-order virtual container to be scheduled lies is modified to be a switching network address corresponding to a secondary low-order cross module (a low-order cross module in the secondary low-order cross device).

As can be seen, in order to accomplish switching from the primary low-order cross device to the secondary low-order cross device, it is necessary to modify the destination address of each cell obtained from conversion of a bit stream including a high-order virtual container in which an SDH low-order virtual container to be scheduled lies. If this procedure is implemented with hardware, then because the switching network address corresponding to a low-order cross module is fixed, i.e., corresponds to a fixed slot on a single board in which a lower-order cross device lies, thus it is necessary for the slot on the single board to be reserved specially for installation of the lower-order cross device to reduce the flexibility of the use of the single board. A status line needs to be additionally connected to notify all other single boards about switching of status of the primary and secondary low-order cross devices, thereby increasing the cost of the switching. The time for the switching may be prolonged if the procedure is implemented with software.

### SUMMARY

An object of the present disclosure is to provide a method and device for primary-secondary protection of a low-order cross device for implementing SDH low-order virtual container scheduling on the basis of a switching network, which can implement rapidly primary-secondary switching of the low-order cross device.

To achieve the above object, various embodiments of the disclosure provide a method for primary-secondary protection of a low-order cross device for implementing SDH low-order virtual container scheduling on the basis of a switching network, where the SDH low-order virtual container scheduling is implemented through the switching network and two or more low-order cross devices connected to the switching network, one of the two or more low-order cross devices which is in a working status is a primary low-order cross device, and the others in a backup status each are a secondary low-order cross device.

The method includes:

allocating a multicast ID as a destination address of a bit stream including a high-order virtual container, the high-order virtual container including the SDH low-order virtual container to be scheduled, and the multicast ID pointing respectively to ports in the switching network which are connected to the two or more low-order cross devices;

closing connecting channels between the switching network and the secondary low-order cross devices; and

opening the connecting channel between the switching network and one of the secondary low-order cross devices upon failure of the primary low-order cross device, the secondary low-order cross device, the connecting channel between which and the switching network is opened, becoming a new primary low-order cross device.

There is also provided a device for implementing primary-secondary protection of a low-order cross device, including two or more low-order cross devices connected to a switching network, and a controller which controls respectively opening and closing of connecting channels between the low-order cross devices and the switching network, and which allocates a multicast ID as a destination address of a bit stream including a high-order virtual container, the multicast ID pointing respectively to ports in the switching network which are connected to the low-order cross devices.

By allocating a multicast ID and controlling opening and closing of connecting channels between the switching network and the primary and secondary low-order cross devices, the present disclosure achieves the purpose of disabling or enabling the low-order cross device, thereby accomplishing primary-secondary switching of the low-order cross device by the use of the multicast technology for the switching network, so as to rapidly implement protection.

Further areas of applicability will become apparent from the description provided herein. It should be understood that the description and specific examples are intended for purposes of illustration only and are not intended to limit the scope of the present disclosure.

### DRAWINGS

The drawings described herein are for illustration purposes only and are not intended to limit the scope of the present disclosure in any way.

FIG. 1 is a schematic diagram illustrating a method for implementing SDH virtual container scheduling by the use of space division and time division cross technologies in the prior art;

FIG. 2 is a schematic diagram illustrating a method for implementing SDH virtual container scheduling by the use of GMPS in the prior art;

FIG. 3 is a schematic diagram illustrating a method for implementing SDH virtual container scheduling based upon a switching network;

FIG. 4 is a schematic diagram illustrating the internal structure of a low-order cross module illustrated in FIG. 3 and a high-order slicing module and a high-order assembly module connected to the low-order cross module;

FIG. 5 is a flow chart illustrating a method for primary-secondary protection of a low-order cross device for implementing SDH low-order virtual container scheduling based upon a switching network according to various embodiments of the disclosure; and

FIG. 6 is a structural diagram illustrating a device for primary-secondary protection of a low-order cross device for implementing SDH low-order virtual container scheduling based upon a switching network according to various embodiments of the disclosure.

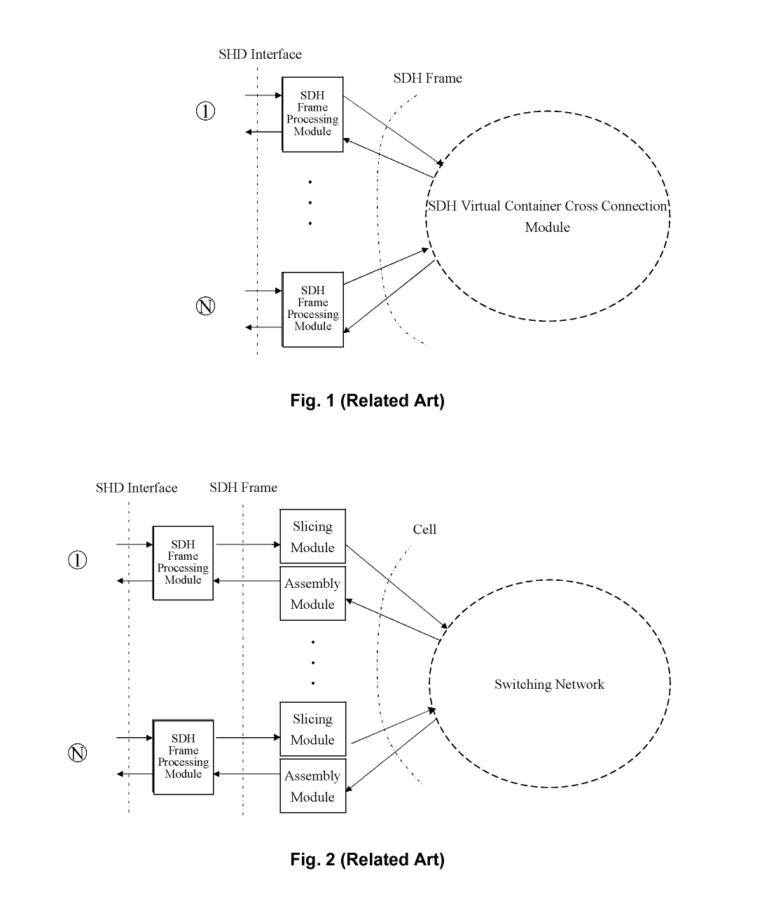

### DETAILED DESCRIPTION

The following description is merely exemplary in nature and is not intended to limit the present disclosure, application, or uses.

Various embodiments of the disclosure are described further in detail as follows in conjunction with the drawings to make the above object, features and advantages thereof more apparent and readily understood.

Various embodiments of the present disclosure provide a method for primary-secondary protection of a low-order cross device for implementing SDH low-order virtual container scheduling on the basis of a switching network, which accomplishes switching of primary and secondary low-order cross devices by the use of multicast technology. According to various embodiments of the present disclosure, the method is implemented as follows.

The SDH low-order virtual container scheduling is implemented through a switching network and two or more low-order cross devices connected to the switching network. One of the two or more low-order cross devices which is in a working status is a primary low-order cross device, and the others in a backup status each is a secondary low-order cross device.

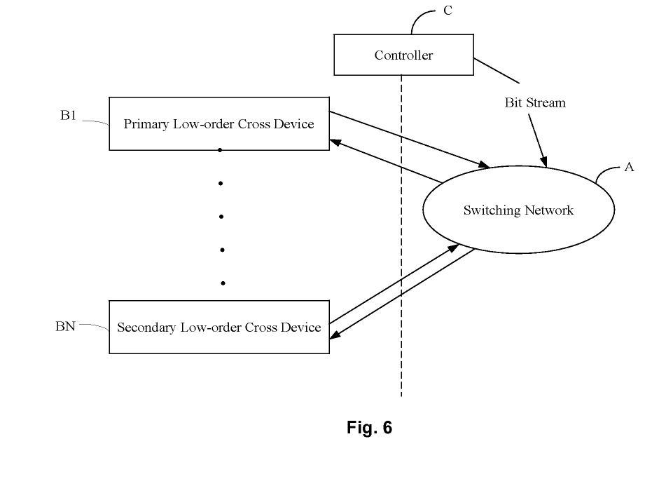

As illustrated in FIG. 5, the method includes:

S01. allocating a multicast ID to each cell for use obtained from conversion of a bit stream including a high-order virtual container in which an SDH low-order virtual container to be scheduled lies, the multicast ID being corresponding to switching network ports in the switching network which are connected to the primary and secondary low-order cross devices;

S02. closing connecting channels in one or two directions between the secondary low-order cross devices and the switching network when the primary low-order cross device works properly; and

S03. opening a connecting channel between one of the secondary low-order cross devices and the switching network when the primary low-order cross device fails, thereby accomplishing primary-secondary switching of the low-order cross device.

Preferably, a connecting channel between the primary low-order cross device and the switching network is closed when the primary low-order cross device fails.

More preferably, firstly a connecting channel between the primary low-order cross device and the switching network is closed, and then a connecting channel between one of the secondary low-order cross devices and the switching network is opened when the primary low-order cross device fails.

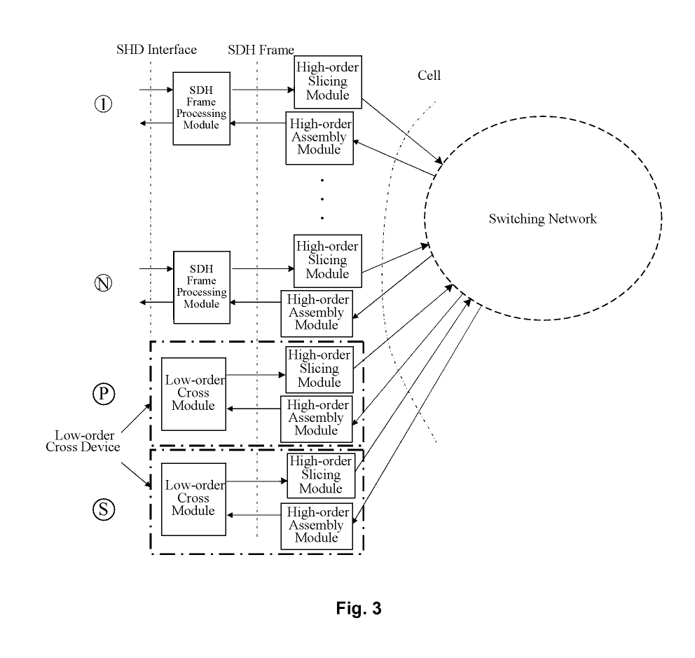

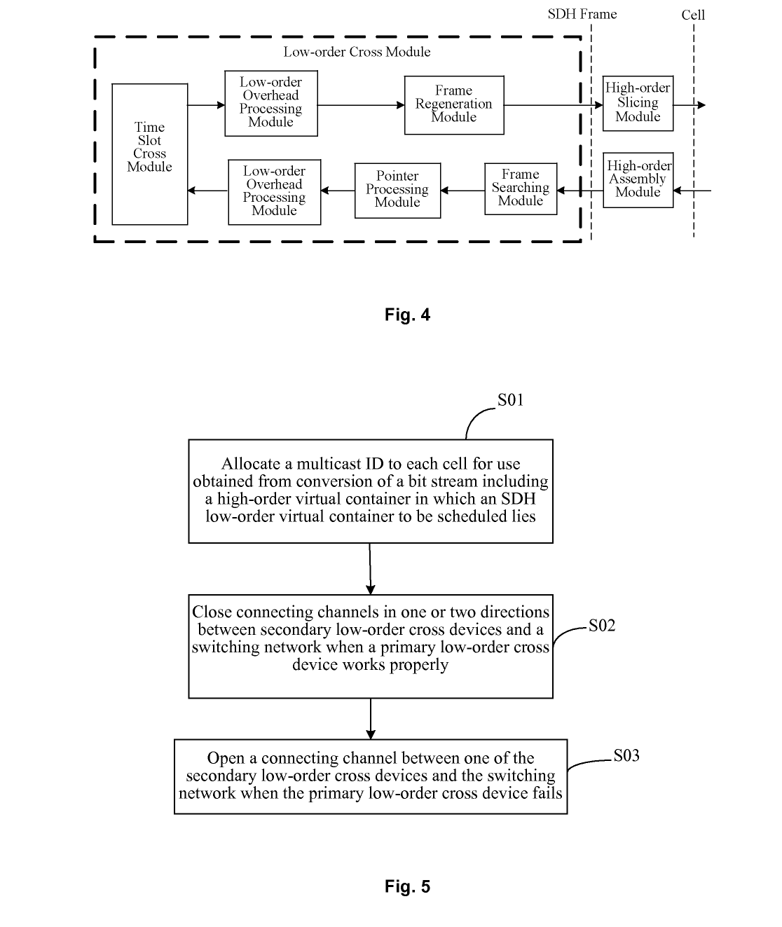

Still referring to FIG. 3, according to various embodiments, when the SDH low-order virtual container scheduling is performed under normal conditions, a bit stream including a high-order virtual container in which an SDH low-order virtual container to be scheduled lies is converted, by an SDH frame processing module and a high-order slicing module, into a cell, the allocated multicast ID is filled in the cell head of the cell, and then the cell is transported to the switching network. The switching network transports the cell to a high-order assembly module connected to a primary low-order cross module dependent upon a destination address in the cell head, i.e., the multicast ID, upon reception of the cell. The high-order assembly module reassembles the received cells into an SDH frame and transports the SDH frame to a primary low-order cross module. At this time, the connecting channels in one or two directions between the secondary low-order cross devices and the switching network are in a closed status, and therefore the cell can not be transported to any secondary low-order cross device and/or no secondary low-order cross device can transport any processed SDH virtual container to the switching network. As to the subsequent processes, the reference can be made of the relevant descriptions above, and these processes are omitted here.

In the above procedure, primary-secondary switching can be performed as follows upon detection of a failure of the primary low-order cross device:

1. determining that the primary low-order cross device fails; and

2. opening a connecting channel between one of the secondary low-order cross devices and the switching network, thereby accomplishing primary-secondary switching of the low-order cross device.

In another embodiment of the present disclosure, firstly a connecting channel between the primary low-order cross device and the switching network is closed, and then a connecting channel between one of the secondary low-order cross devices and the switching network is opened upon determination of a failure of the primary low-order cross device. In a further embodiment of the present disclosure, firstly a connecting channel between one of the secondary low-order cross devices and the switching network is opened, and then a connecting channel between the primary low-order cross device and the switching network is closed upon determination of a failure of the primary low-order cross device.

There may be one or more secondary low-order cross devices according to specific scenarios. It can be readily appreciated that in the case of only one secondary low-order cross device, the method according to the present disclosure can allocates a bi-cast ID to the cell for use obtained from conversion of a bit stream including a high-order virtual container in which an SDH low-order virtual container to be scheduled lies, the bi-cast ID being corresponding to two ports of the switching network. In other words, a bi-cast ID is a specific scenario of a multicast ID.

Correspondingly, a device for implementing primary-secondary protection of a low-order cross device is provided. As illustrated in FIG. 6, the device includes two or more low-order cross devices B1-BN connected to a switching network A, and a controller C which controls respectively the opening and closing of connecting channels between the low-order cross devices B1-BN and the switching network, and which allocates a multicast ID as a destination address of a bit stream including a high-order virtual container, the multicast ID pointing respectively to ports, which are connected to the low-order cross devices B1-BN, in the switching network.

Although the exemplary embodiments of the present disclosure have been described, those skilled in the art can modify the various embodiments as disclosed here when reading and grasping the principle and teaching of the present disclosure. For instance, the specification has presented descriptions of the exemplary embodiments of the present disclosure based upon conversion of a bit stream including an SDH virtual container to be scheduled into a cell, but the method according to the present disclosure can also be applied in conversion of an SDH virtual container to be scheduled into packets. Accordingly, it is intended that the scope of the present disclosure shall be defined by the appended claims.

What is claimed is:

1. A method for primary-secondary protection of a low-order cross device for implementing SDH low-order virtual container scheduling on the basis of a switching network, wherein the SDH low-order virtual container scheduling is implemented through the switching network and two or more low-order cross devices connected to the switching network, one of the two or more low-order cross devices which is in a working status is a primary low-order cross device, and the others in a backup status each is a secondary low-order cross device,
wherein the method comprises:
allocating a multicast ID as a destination address of a bit stream including a high-order virtual container, the high-order virtual container including an SDH low-order virtual container to be scheduled, and the multicast ID pointing respectively to ports in the switching network which are connected to the two or more low-order cross devices;
closing connecting channels between the switching network and the secondary low-order cross devices; and
opening a connecting channel between the switching network and one of the secondary low-order cross devices upon failure of the primary low-order cross device.

2. The method according to claim 1, wherein the bit stream has a form of cells.

3. The method according to claim 2, wherein the bit stream is converted into the form of cells through being sliced.

4. The method according to claim 1, wherein the bit stream has a form of packets.

5. The method according to claim 1, wherein closing connecting channels between the switching network and the secondary low-order cross devices comprises:
closing the connecting channels in one or more directions between the switching network and the secondary low-order cross devices.

6. The method according to claim 1, wherein opening a connecting channel between the switching network and one of the secondary low-order cross devices upon failure of the primary low-order cross device further comprises:
closing a connecting channel between the switching network and the primary low-order cross device.

7. The method according to claim 6, wherein closing a connecting channel between the switching network and the primary low-order cross device is followed by opening a connecting channel between the switching network and one of the secondary low-order cross devices.

8. The method according to claim 1, wherein the SDH low-order virtual container scheduling is implemented in such a manner that two low-order cross devices are connected to the switching network.

9. The method according to claim 8, wherein the multicast ID is a bi-cast ID, the bi-cast ID pointing respectively to the ports in the switching network which are connected to the two low-order cross devices.

10. A device for implementing primary-secondary protection of a low-order cross device, comprising two or more low-order cross devices (B1-BN) connected to a switching network, wherein the device further comprises a controller (C) which controls respectively opening and closing of connecting channels between the low-order cross devices (B1-BN) and the switching network, and which allocates a multicast ID as a destination address of a bit stream including a high-order virtual container, the multicast ID pointing respectively to ports, which are connected to the low-order cross devices (B1-BN), in the switching network.
